(19) United States
(12) Patent Application Publication
(10) Pub. No.: US 2026/0262509 A1
(43) Pub. Date: Sep. 3, 2026

(54) ELECTRONIC DEVICE

(71) Applicant: Innolux Corporation, Miaoli County (TW)

(72) Inventors: Yoshitada Ozaki, Miaoli County (TW); Takanobu Nakagawa, Miaoli County (TW); Yusei Ukawa, Miaoli County (TW); Minoru Shibazaki, Miaoli County (TW); Masato Nishimoto, Miaoli County (TW)

(73) Assignee: Innolux Corporation, Miaoli County (TW)

(21) Appl. No.: 19/069,182

(22) Filed: Mar. 3, 2025

(51) Int. Cl. H01L 23/495; H01L 23/00; H01L 23/14

(52) U.S. Cl. CPC H10W 70/453; H10W 70/695; H10W 90/724

(57) ABSTRACT

An electronic device includes a flexible substrate, a first conductive feature, a second conductive feature, a first organic interlayer dielectric layer and an electronic component. The first conductive feature is disposed on the flexible substrate. The second conductive feature is disposed on the first conductive feature. The first organic interlayer dielectric layer is disposed between the first conductive feature and the second conductive feature. The electronic component is disposed on the flexible substrate and electrically connected to at least one of the first conductive feature and the second conductive feature. At least one of the first conductive feature and the second conductive feature includes an organic material and a conductive material.

### BACKGROUND

### Technical Field

This disclosure relates to an electronic device.

### Description of Related Art

Flexible hybrid electronics (FHE) are soft, flexible and easy to bend, allowing products to be designed according to needs without being limited to fixed forms. Therefore, FHE technology can be integrated with textile, medical, logistics, warehousing, automotive and other industries to create unlimited business prospects. In FHE products, electronic components are usually bonded via solder to conductive features (e.g., pad portions) printed on the substrate. Therefore, the adhesion between the conductive features and the substrate, the adhesion between the conductive features and the solder and the integrity of the conductive features (e.g., pad portions) after solder is formed thereon will affect the reliability and/or productivity of FHE products.

### SUMMARY

The disclosure provides an electronic device that helps improve reliability and/or productivity.

In an embodiment of the disclosure, an electronic device includes a flexible substrate, a first conductive feature, a second conductive feature, a first organic interlayer dielectric layer and an electronic component. The first conductive feature is disposed on the flexible substrate. The second conductive feature is disposed on the first conductive feature. The first organic interlayer dielectric layer is disposed between the first conductive feature and the second conductive feature. The electronic component is disposed on the flexible substrate and electrically connected to at least one of the first conductive feature and the second conductive feature. At least one of the first conductive feature and the second conductive feature includes an organic material and a conductive material.

In an embodiment of the disclosure, an electronic device includes a substrate, a conductive feature and an electronic component. The conductive feature is disposed on the substrate and includes a lower conductive layer and an upper conductive layer disposed on the lower conductive layer. The electronic component is disposed on the substrate and electrically connected to the conductive feature. The lower conductive layer has a first resin content, and the upper conductive layer has a second resin content less than the first resin content.

In an embodiment of the disclosure, an electronic device includes a flexible substrate, a conductive feature, a first electronic component, a connection component and a protective layer. The conductive feature is disposed on the flexible substrate and includes an organic material and a conductive material. The first electronic component is disposed on the flexible substrate and electrically connected to the conductive feature. The connection component is disposed on the flexible substrate and electrically connected to the first electronic component. The conductive feature and the first electronic component are covered by the protective layer, and the connection component is exposed by the protective layer.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is a partial top view of an electronic device according to some embodiments of the disclosure.

FIG. 2, FIG. 3A and FIG. 3B are cross-sectional views corresponding to section lines A-A′, B1-B1′ and B2-B2′ in FIG. 1.

FIG. 4 is a partial top view of an electronic device according to some embodiments of the disclosure.

FIG. 5 and FIG. 6 are cross-sectional views corresponding to section lines C-C′ and D-D′ in FIG. 4.

FIG. 7 is a partial top view of an electronic device according to some embodiments of the disclosure.

FIG. 8 is a cross-sectional view corresponding to a section line E-E′ in FIG. 7.

FIG. 9 is a partial top view of an electronic device according to some embodiments of the disclosure.

FIG. 10 is a schematic top view of an electronic device according to some embodiments of the disclosure.

FIG. 11 is a cross-sectional view corresponding to a section line F-F′ in FIG. 10.

### DESCRIPTION OF THE EMBODIMENTS

Reference will now be made in detail to the exemplary embodiments of the disclosure, examples of which are illustrated in the accompanying drawings. Whenever possible, the same reference numerals are used in the drawings and descriptions to refer to the same or similar parts.

Throughout this specification and the claims, certain words are used to refer to specific components. One of ordinary skill in the art will appreciate that manufacturers of electronic devices may refer to the same component by different names. This disclosure is not intended to differentiate between components that have the same function but have different names. In the following description and claims, the words “include” and “comprise” are open-ended terms and should therefore be interpreted to mean “includes, but is not limited to . . . ”.

The directional terms mentioned in this disclosure, such as “up”, “down”, “front”, “back”, “left”, “right”, etc., are only for reference to the directions in the accompanying drawings. Accordingly, the directional terms used are illustrative and not limiting of the disclosure. In the drawings, each figure illustrates the general features of methods, structures, and/or materials used in particular embodiments. However, these drawings should not be interpreted as defining or limiting the scope or nature encompassed by these embodiments. For example, the relative sizes, thicknesses, and locations of various layers, regions, and/or structures may be reduced or exaggerated for clarity.

One structure (or layer, component, substrate) described in the disclosure is located on/above another structure (or layer, component, substrate), which may mean that the two structures are adjacent to each other and are directly connected, or that the two structures are adjacent to each other and are not directly connected. Non-directly connected means that there is at least one intermediary structure (or intermediary layer, intermediary component, intermediary substrate, intermediary spacer) between the two structures, with the lower surface of one structure adjacent to or directly connected to the upper surface of the intermediary structure, and the upper surface of the other structure adjacent to or directly connected to the lower surface of the intermediary structure. The intermediary structure may be a single or multi-layered solid or non-solid structure, without limitation. In the disclosure, when a structure is disposed “on” other structures, it may mean that a structure is “directly” on the other structures, or that a structure is “indirectly” on the other structures, that is, a structure and other structures have at least one other structure sandwiched between them.

The terms “approximately”, “substantially” or “generally” are generally interpreted as being within 10% of the given value or range, or within 5%, 3%, 2%, 1% or 0.5% of the given value or range. In addition, the terms “the range is from the first value to the second value”, “the range is between the first value and the second value” indicate that the range includes the first value, the second value, and other values in between.

The ordinal numbers used in the specification and claims, such as “first” and “second”, are used to qualify the components, and do not in themselves imply or represent any previous ordinal number of the component or components, nor do they represent the order of one component or component with another, or the order of the manufacturing method. The use of these numbers is intended only to enable a component with a certain designation to be clearly distinguished from another component with the same designation. The same terminology may not be used in the claims and the specification. Accordingly, the first component in the specification may be the second component in the claims.

The electrical connection or coupling described in the disclosure may refer to either a direct connection or an indirect connection, in which the terminals of the two circuit elements are directly connected or connected to each other by a conductor line, or an indirect connection in which the terminals of the two circuit elements are connected by a switch, a diode, a capacitor, an inductor, a resistor, or any other suitable component, or a combination of the foregoing, without limitation.

In this disclosure, the thickness, length, and width can be measured by using an optical microscope (OM), and the thickness or width can be measured by cross-sectional images in an electron microscope, but is not limited thereto. In addition, there may be a certain amount of error between any two values or directions used for comparison. Furthermore, the expression “the given range is the first value to the second value”, “the given range falls within the range of the first value to the second value” or “the given range is between the first value to the second value” means that the given range includes the first value, the second value, and other values in between. If the first direction is perpendicular to the second direction, the angle between the first direction and the second direction can be between 80 degrees and 100 degrees; if the first direction is parallel to the second direction, the angle between the first direction and the second direction can be between 0 degrees and 10 degrees.

Unless otherwise defined, all terms used herein, including technical and scientific terms, have the same meanings as are commonly understood by those skilled in the art. It is to be understood that these terms, such as those defined in commonly used dictionaries, should be interpreted as having a meaning consistent with the context or background of the relevant technology and the present disclosure, and should not be interpreted in an idealized or overly formalized manner, except as specifically defined in the embodiments of the present disclosure.

In the disclosure, the electronic device may include a display device, a backlight device, an antenna device, a packaging device, a sensing device, or a splicing device, but is not limited thereto. The electronic device may be a bendable or flexible electronic device. The display device can be a non-self-illuminating display device or a self-illuminating display device. The display device may include, for example, liquid crystal, light-emitting diode, fluorescence, phosphor, quantum dot (QD), other suitable display media, or a combination of the above. The antenna device may include, for example, a reconfigurable intelligent surface (RIS), a frequency selective surface (FSS), a radio frequency filter (RF-Filter), a polarizer, a resonator, or an antenna. (Antenna) et al. The antenna may be a liquid crystal antenna or a varactor diode antenna. The sensing device may be a sensing device that senses capacitance, light, heat energy, or ultrasonic waves, but is not limited thereto. In the disclosure, the electronic device may include electronic components, and the electronic components may include passive components and active components, such as capacitors, resistors, inductors, diodes, transistors. Diodes may include light-emitting diodes, varactor diodes, or photodiodes. The light-emitting diode may include, for example, an organic light-emitting diode (OLED), a sub-millimeter light-emitting diode (mini-LED), a micro light-emitting diode (micro-LED), or a quantum dot light-emitting diode (quantum dot LED), but not limited thereto. The splicing device may be, for example, a display splicing device or an antenna splicing device, but is not limited thereto. It should be noted that the electronic device can be any combination of the above, but is not limited thereto. The packaging device may be suitable for Wafer-Level Package (WLP) technology or Panel-Level Package (PLP) technology, such as chip first or RDL first process. In addition, the shape of the electronic device may be a rectangular shape, a circular shape, a polygonal shape, a shape with curved edges, or other suitable shapes. Electronic devices may have peripheral systems such as drive systems, control systems, and light source systems to support display devices, antenna devices, wearable devices (e.g., including augmented reality or virtual reality), vehicle-mounted devices (e.g., including car windshields), or splicing devices.

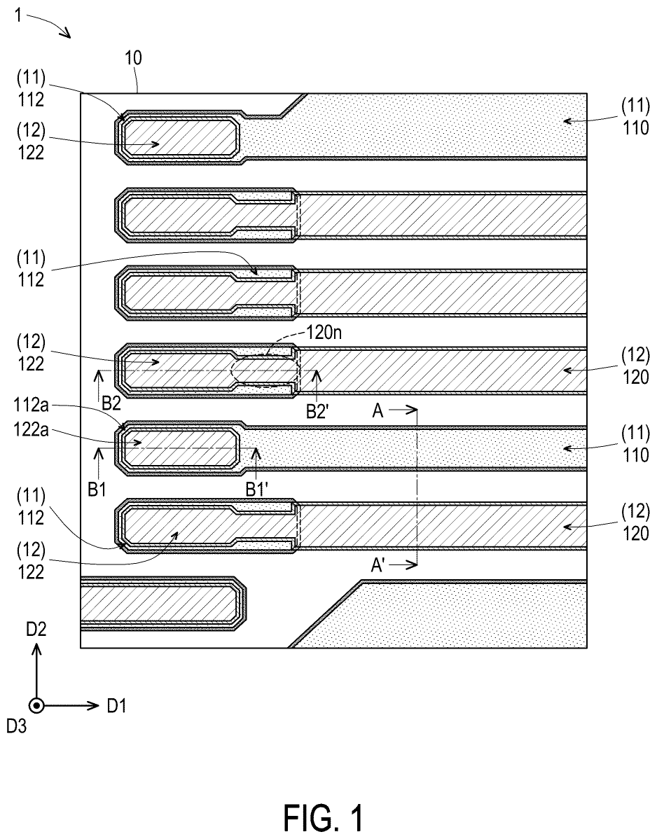

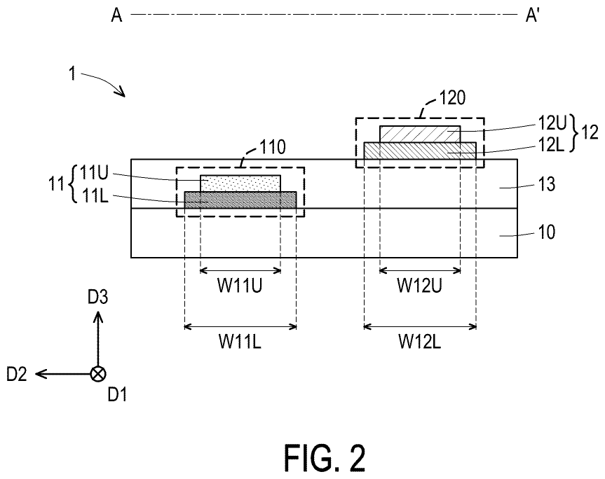

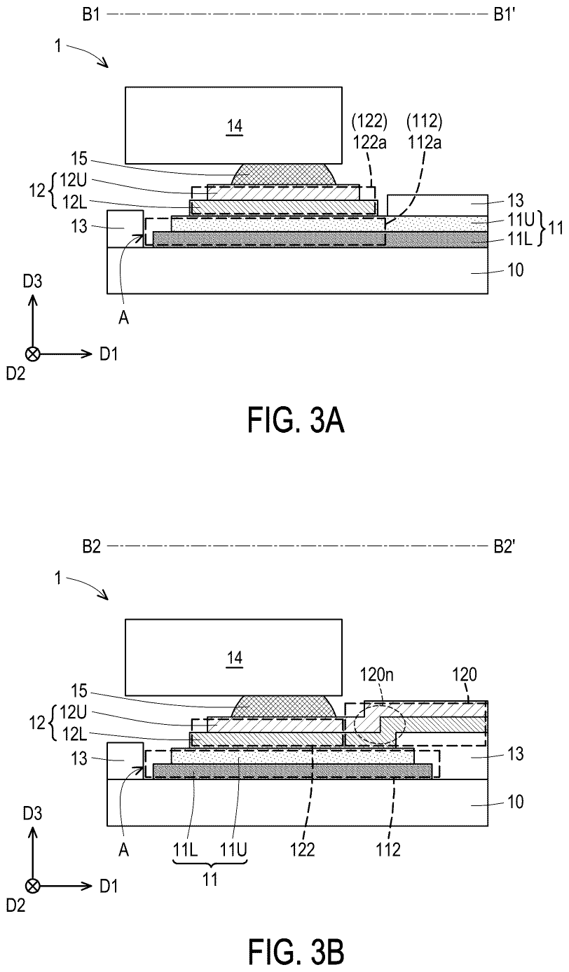

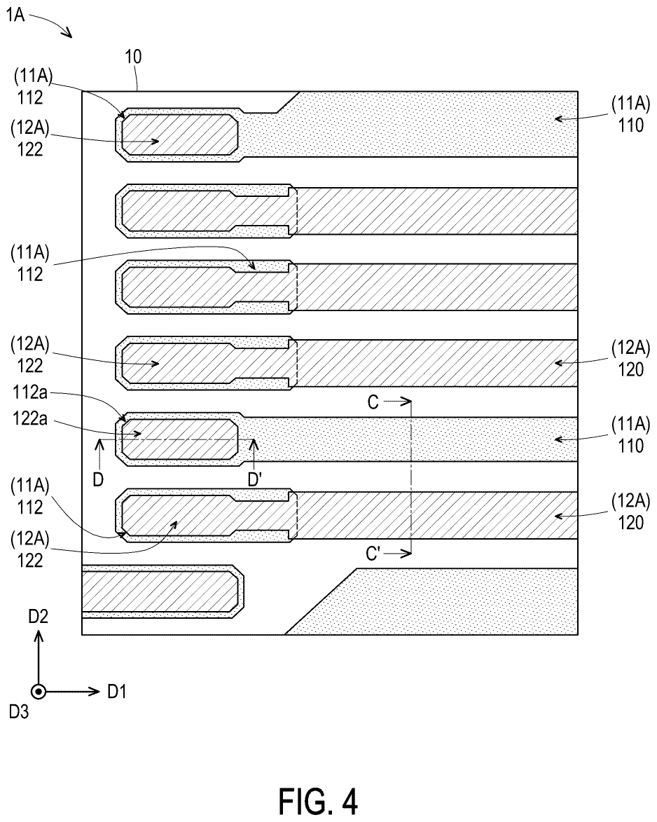

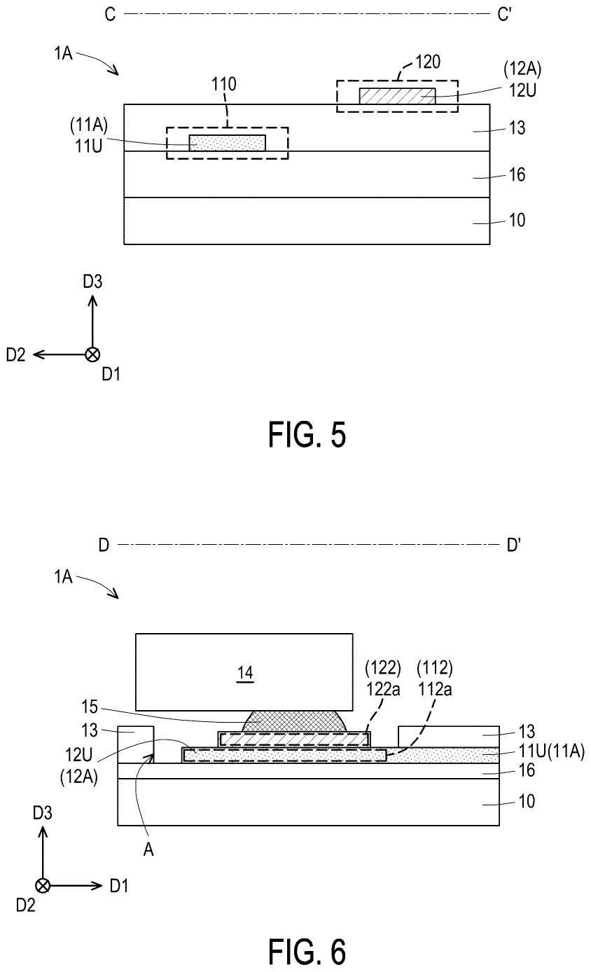

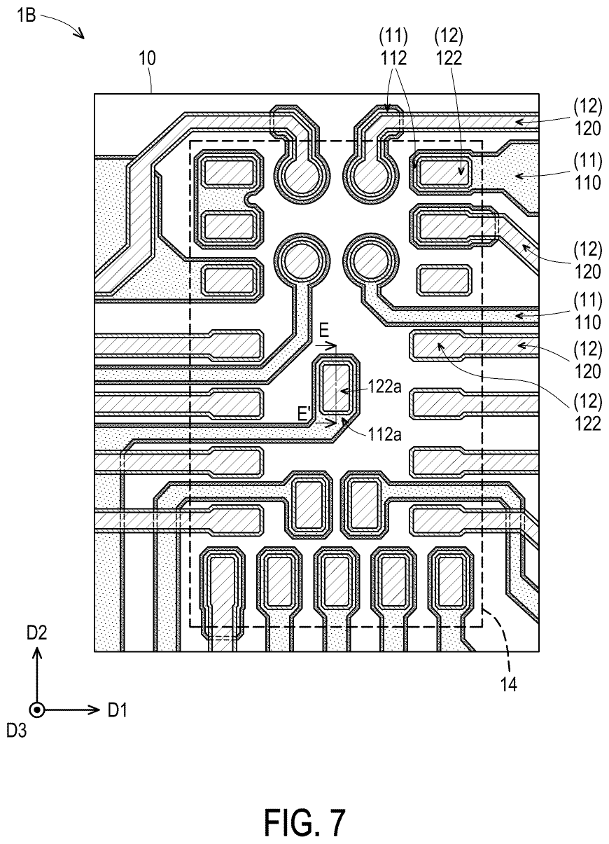

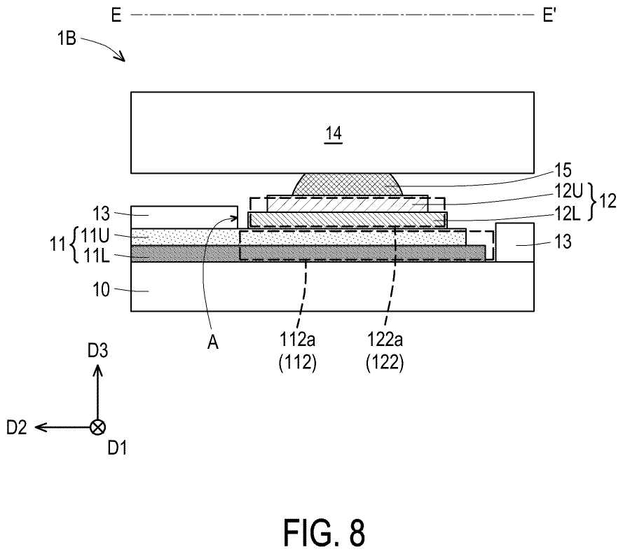

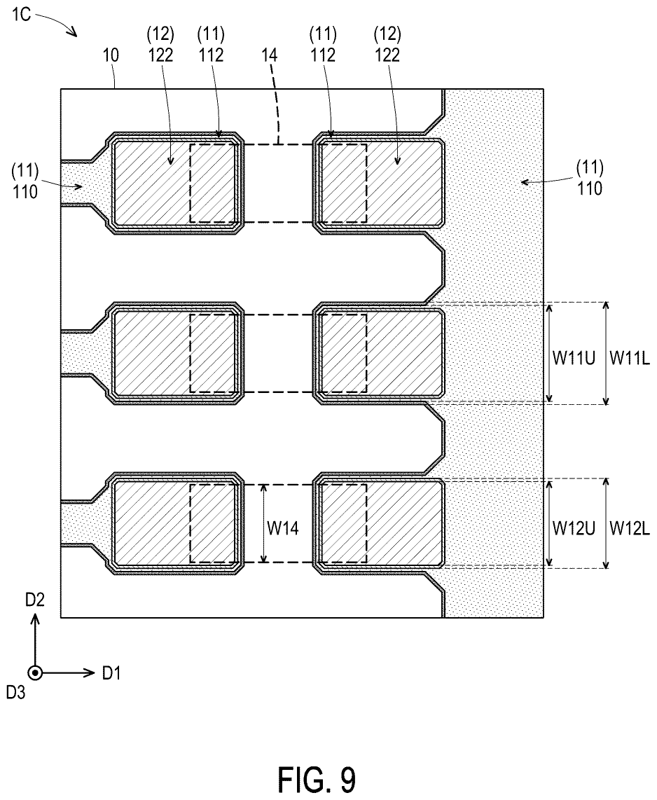

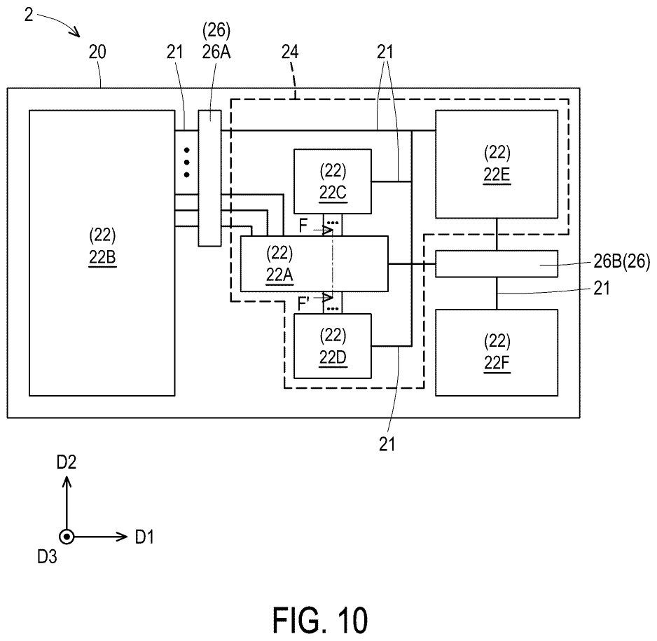

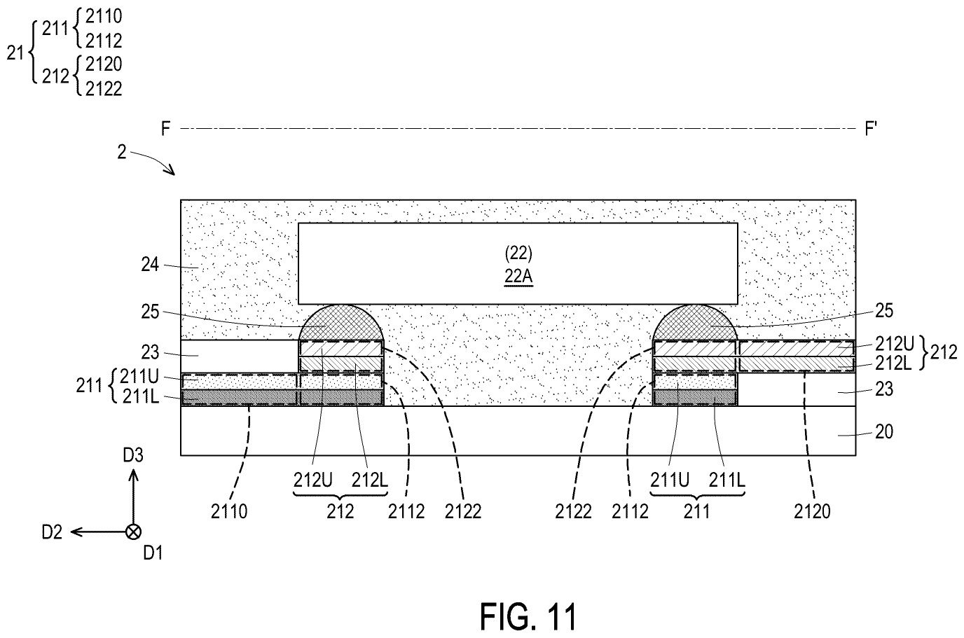

FIG. 1 is a partial top view of an electronic device according to some embodiments of the disclosure. FIG. 2, FIG. 3A and FIG. 3B are cross-sectional views corresponding to section lines A-A′, B1-B1′ and B2-B2′ in FIG. 1. FIG. 4 is a partial top view of an electronic device according to some embodiments of the disclosure. FIG. 5 and FIG. 6 are cross-sectional views corresponding to section lines C-C′ and D-D′ in FIG. 4. FIG. 7 is a partial top view of an electronic device according to some embodiments of the disclosure. FIG. 8 is a cross-sectional view corresponding to a section line E-E′ in FIG. 7. FIG. 9 is a partial top view of an electronic device according to some embodiments of the disclosure. FIG. 10 is a schematic top view of an electronic device according to some embodiments of the disclosure. FIG. 11 is a cross-sectional view corresponding to a section line F-F′ in FIG. 10. In top views of the present disclosure, some elements or layers (e.g., electronic component(s) and organic interlayer dielectric layer(s)) are not shown for simplicity and clarity of the top views. For the elements or layers not shown in the top views, please refer to corresponding cross-sectional views and relevant descriptions in the specification for details. It should be noted that the following embodiments can be replaced, reorganized, and mixed with features of several different embodiments without departing from the spirit of the disclosure to complete other embodiments. Features in various embodiments may be mixed and matched as long as they do not violate the spirit of the invention or conflict with each other.

Please refer to FIG. 1 to FIG. 3B, an electronic device 1 may include a flexible substrate 10, a first conductive feature 11, a second conductive feature 12, a first organic interlayer dielectric layer 13 and an electronic component 14. The first conductive feature 11 is disposed on the flexible substrate 10. The second conductive feature 12 is disposed on the first conductive feature 11. The first organic interlayer dielectric layer 13 is disposed between the first conductive feature 11 and the second conductive feature 12. The electronic component 14 is disposed on the flexible substrate 10 and electrically connected to at least one of the first conductive feature 11 and the second conductive feature 12. At least one of the first conductive feature 11 and the second conductive feature 12 includes an organic material and a conductive material.

Specifically, the electronic device 1 is, for example, an FHE device that can be applied to logistics, healthcare, infrastructure monitoring, manufacturing management or the like, but is not limited thereto.

The flexible substrate 10 is configured to carry the first conductive feature 11, the second conductive feature 12, the first organic interlayer dielectric layer 13 and the electronic component 14. The flexible substrate 10 may include plastic materials such as polyethylene naphthalate (PEN), polyethylene terephthalate (PET), polypropylene (PP), polyimide (PI), polycarbonate (PC), other suitable flexible materials, or combinations of the aforementioned plastic materials, but is not limited thereto. Alternatively, the flexible substrate 10 may include elastic materials such as rubber, paper, cellulose nanofiber, other suitable elastic materials, or combinations of the aforementioned elastic materials, but is not limited thereto.

The first conductive feature 11, the first organic interlayer dielectric layer 13 and the second conductive feature 12 may be sequentially formed on the flexible substrate 10 through, for example, printing methods, such as screen printing, ink jet printing, gravure printing, flexography printing or the like, but not limited thereto.

The first conductive feature 11 refers to the conductive feature that is formed prior to the first organic interlayer dielectric layer 13, while the second conductive feature 12 refers to the conductive feature that is formed subsequent to the first organic interlayer dielectric layer 13. In some embodiments, at least one of the first conductive feature 11 and the second conductive feature 12 includes a lower conductive layer (e.g., 11L, 12L) and an upper conductive layer (e.g., 11U, 12U) disposed on the lower conductive layer. For example, as shown in FIG. 2, FIG. 3A or FIG. 3B, the first conductive feature 11 may include a lower conductive layer 11L and an upper conductive layer 11U disposed on the lower conductive layer 11L, and the second conductive feature 12 may include a lower conductive layer 12L and an upper conductive layer 12U disposed on the lower conductive layer 12L, but the disclosure is not limited thereto. In other embodiments, as shown in FIG. 4 to FIG. 6, at least one of the first conductive feature 11 and the second conductive feature 12 may include a single conductive layer (e.g., 11U, 12U).

In the embodiments in which at least one of the first conductive feature 11 and the second conductive feature 12 includes a lower conductive layer (e.g., 11L, 12L) and an upper conductive layer (e.g., 11U, 12U) disposed on the lower conductive layer, the lower conductive layer (e.g., 11L, 12L) has a first resin content, and the upper conductive layer (e.g., 11U, 12U) has a second resin content less than the first resin content. In addition, the lower conductive layer (e.g., 11L, 12L) has a first metal content, and the upper conductive layer (e.g., 11U, 12U) has a second metal content greater than the first metal content. The resin or metal content described above may refer to weight percent or atomic percent of carbon or metal element and can be analyzed using, for example, SEM-EDX.

Specifically, each of the upper conductive layer (e.g., 11U, 12U) and the lower conductive layer (e.g., 11L, 12L) can include an organic material as a binder and a conductive material as a filler. In some embodiments, the organic material includes resin, and the conductive material includes metal. For example, the organic material of the upper conductive layer (e.g., 11U, 12U) includes cellulosic resin, the conductive material of the upper conductive layer (e.g., 11U, 12U) includes silver, copper or a combination of the above, the organic material of the lower conductive layer (e.g., 11L, 12L) includes urethane resin, and the conductive material of the lower conductive layer (e.g., 11L, 12L) includes silver, copper or a combination of the above, but is not limited thereto.

For a conductive layer (e.g., 11L, 11U, 12L, 12U) that includes a conductive material as well as an organic material, the resin content of the conductive layer mainly originates from the organic material of the conductive layer, and the metal content of the conductive layer mainly originates from the conductive material of the conductive layer. Through the design that the first resin content of the lower conductive layer (e.g., 11L, 12L) is greater than the second resin content of the upper conductive layer (e.g., 11U, 12U), the adhesion of the lower conductive layer (e.g., 11L, 12L) to the flexible substrate 10 can be improved, thereby improving the problem of detachment/peeling of the conductive features (e.g., 11, 12) from the flexible substrate 10. Through the design that the second resin content of the upper conductive layer (e.g., 11U, 12U) is less than the first resin content of the lower conductive layer (e.g., 11L, 12L), the adhesion of the upper conductive layer (e.g., 11U, 12U) to the solder 15 (configured to join/fix the electronic component 14) can be improved, thereby improving the problem of detachment/peeling of the electronic component 14 from the conductive features (e.g., 11, 12). In addition, by increasing the metal content in the upper conductive layer (e.g., 11U, 12U), the overall impedance of the conductive features (e.g., 11, 12) can be reduced, which is beneficial to signal transmission. For example, the second metal content of the upper conductive layer (e.g., 11U, 12U) may be larger than or equal to 80wt %, while the first metal content of the lower conductive layer (e.g., 11L, 12L) may be smaller than 80wt %. Moreover, the multi-layer (e.g., two-layer) structure of the conductive features (e.g., 11, 12) improves the flexibility of the conductive features (e.g., 11, 12), making the electronic device 1 flexible or easy to bend.

In some embodiments, in a cross-sectional view, a maximum width (e.g., W11U, W12U) of the upper conductive layer (e.g., 11U, 12U) may be smaller than a maximum width (e.g., W11L, W12L) of the lower conductive layer (e.g., 11L, 12L). For example, as shown in FIG. 2, the maximum width W11U of the upper conductive layer 11U is smaller than the maximum width W11L of the lower conductive layer 11L, and the maximum width W12U of the upper conductive layer 12U is smaller than the maximum width W12L of the lower conductive layer 12L.

During the printing process to form the first conductive feature 11, the first organic interlayer dielectric layer 13 and the second conductive feature 12, not only variations in the printing process (such as the squeegeeing stretch of the printing plate and interlayer alignment), but also variations of the printing plate itself (such as the pattern position and dimensional accuracy of the printing plate) can reduce the printing quality and even reduce the yield of the electronic device 1. By designing the cross-sectional width of the lower conductive layer to be larger than the cross-sectional width of the upper conductive layer, material overflow/bleed-out during the printing process can be suppressed, which helps to improve short circuits caused by material overflow/bleed-out and/or improve yields.

In some embodiments, as shown in FIG. 1, the electronic device 1 includes a plurality of first conductive features 11 and a plurality of second conductive features 12. In some embodiments, as shown in FIG. 1, the plurality of first conductive features 11 includes one or more line portions 110 and one or more pad portions 112, and the plurality of second conductive features 12 includes one or more line portions 120 and one or more pad portions 122, but are not limited thereto.

In some embodiments, as shown in FIG. 1, the line portions (e.g., 110, 120) extend along a first direction D1 and arranged along a second direction D2 different from the first direction D1. The first direction D1 and the second direction D2 are perpendicular to a thickness direction (e.g., a third direction D3) of the electronic device 1 and are, for example, perpendicular to each other, but is not limited thereto. Some pad portions 112 may be connected to some corresponding line portions 110, and other pad portions 112 may not be connected to any line portions 110. Some pad portions 122 may be connected to some corresponding line portions 120, and other pad portions 122 may not be connected to any line portions 120. Each pad portion 112 may be overlapped with a corresponding pad portion 122 along the third direction D3. For example, as shown in FIG. 1, FIG. 3A or FIG. 3B, the first conductive feature 11 may include a first pad portion 112a, and the second conductive feature 12 may include a second pad portion 122a disposed directly on the first pad portion 112a, namely, the second pad portion 122a is in contact with the first pad portion 112a.

The first organic interlayer dielectric layer 13 is disposed on the flexible substrate 10. In some embodiments, as shown in FIG. 2 and FIG. 3A, the line portions 110 of the first conductive features 11 are covered by the first organic interlayer dielectric layer 13, the pad portions 112 of the first conductive features 11 are exposed by the first organic interlayer dielectric layer 13, the line portions 120 of the second conductive features 12 are disposed on the first organic interlayer dielectric layer 13, and the pad portions 122 of the second conductive features 12 are disposed directly on the pad portions 112 of the first conductive features 11 exposed by the first organic interlayer dielectric layer 13. For example, the first organic interlayer dielectric layer 13 includes an opening A, and the first pad portion 112a and the second pad portion 122a are disposed in the opening A. The first organic interlayer dielectric layer 13 may include talc and polyester resin, but not limited thereto. In some embodiments, as shown in FIG. 3A or FIG. 3B, the electronic component 14 is bonded on the first pad portion 112a and the second pad portion 122a through, for example, solder 15. The electronic component 14 may be a sensor, a microprocessor, a radio frequency chip, a power supply IC or other ICs.

By forming multiple conductive layers (e.g., 11L, 11U, 12L, 12U) at areas where solder 15 is to be formed, the risk of disconnection or poor connection between the electronic component 14 and the pad portions (e.g., 112, 122) due to pad portion leaching (conductive layer erosion/damage by the solder 15) during the soldering process can be reduced.

In some embodiments, as shown in FIG. 1 and FIG. 3B, the line portions 120 of the second conductive features 12 include necked end portions 120n connected to the pad portions 122 of the second conductive features 12, wherein the necked end portions 120n are located at the edge of the opening A of the first organic interlayer dielectric layer 13 and have a smaller line width (e.g., width along the second direction D2) than other portions of the line portions 120 of the second conductive features 12. During the printing process (e.g., screen printing) for forming the second conductive features 12, the emulsion of screen-printing plate helps to prevent the ink paste from leaking and serves to form the desired patterns/features. However, when the printing surface is significantly uneven (e.g., there is a height difference between the first organic interlayer dielectric layer 13 and the pad portions 112 of the first conductive features 11), gaps will be generated between the emulsion and the printing surface, causing ink leakage (material overflow/bleed-out) during the printing process. Through the necked end portions 120n at the edge of the opening A of the first organic interlayer dielectric layer 13, the risk of short circuits between adjacent wirings can be reduced.

Please refer to FIG. 4 to FIG. 6, an electronic device 1A may include the flexible substrate 10, first conductive features 11A, second conductive features 12A, the first organic interlayer dielectric layer 13, the electronic component 14 and the solder 15, wherein at least one of the first conductive feature 11A and the second conductive feature 12A includes a single conductive layer (e.g., 11U, 12U). In addition, the electronic device 1A further includes a second organic interlayer dielectric layer 16 disposed between the flexible substrate 10 and the first conductive feature 11A to improve the adhesion between the single conductive layer (e.g., 11U, 12U) and the flexible substrate 10. The second organic interlayer dielectric layer 16 may include talc and polyester resin, but not limited thereto.

By forming multiple conductive layers (e.g., 11U, 12U) at areas where solder 15 is to be formed, the risk of disconnection or poor connection between the electronic component 14 and the pad portions (e.g., 112, 122) due to pad portion leaching (conductive layer erosion/damage by the solder 15) during the soldering process can be reduced.

Please refer to FIG. 7 and FIG. 8, an electronic device 1B may include the flexible substrate 10, the first conductive features 11, the second conductive features 12, the first organic interlayer dielectric layer 13, the electronic component 14 and the solders 15, wherein the electronic component 14 is bonded to the pad portions 112 of the first conductive features 11 and the pad portions 122 of the second conductive features 12 through solders 15, and the pad portions 112 of the first conductive features 11 and the pad portions 122 of the second conductive features 12 are exposed by the opening A of the first organic interlayer dielectric layer 13.

By forming multiple conductive layers (e.g., 11L, 11U, 12L, 12U) at areas where solder 15 is to be formed, the risk of disconnection or poor connection between the electronic component 14 and the pad portions (e.g., 112, 122) due to pad portion leaching (conductive layer erosion/damage by the solder 15) during the soldering process can be reduced.

Please refer to FIG. 9, in an electronic device 1C, three electronic components 14 arranged along the second direction D2 are shown, wherein each electronic component 14 is bonded to two pad portions 122 adjacently disposed along the first direction D1. In such configuration, the widths (e.g., W11U, W11L) of the pad portions 112 of the first conductive features 11 along the second direction D2 are designed to be close to the widths (e.g., W12U, W12L) of the pad portions 122 of the second conductive features 12 along the second direction D2 to reduce defects caused by the electronic component 14 rotating during the reflow process and then short-circuited to an adjacent pad portion 122. In addition, in the second direction D2, the widths (e.g., W11U, W11L) of the pad portions 112 and the widths (e.g., W12U, W12L) of the pad portions 122 may be equal to or close to but greater than the width W14 of the electronic component 14 to facilitate the bonding of the electronic component 14. Each pad portion 112 and a corresponding pad portion 122 as a whole may be referred to as a peninsula structure.

Please refer to FIG. 10 and FIG. 11, an electronic device 2 includes a substrate 20, a conductive feature 21 and an electronic component 22. The conductive feature 21 is disposed on the substrate 20 and includes a lower conductive layer 21L and an upper conductive layer 21U disposed on the lower conductive layer 21L. The electronic component 22 is disposed on the substrate 20 and electrically connected to the conductive feature 21. The lower conductive layer 21L has a first resin content, and the upper conductive layer 21U has a second resin content less than the first resin content.

The substrate 20 may be, for example, a flexible substrate that includes polyethylene naphthalate (PEN), plastic materials such as polyethylene terephthalate (PET), polypropylene (PP), polyimide (PI), polycarbonate (PC), other suitable flexible materials, or combinations of the aforementioned plastic materials, but is not limited thereto. Alternatively, the flexible substrate 20 may include elastic materials such as rubber, paper, cellulose nanofiber, other suitable elastic materials, or combinations of the aforementioned elastic materials, but is not limited thereto.

In some embodiments, the electronic device 2 includes a plurality of conductive features 21 and an organic interlayer dielectric layer 23, wherein the plurality of conductive features 21 includes a plurality of first conductive features 211 and a plurality of second conductive features 212, and the plurality of first conductive features 211, the organic interlayer dielectric layer 23 and the plurality of second conductive features 212 are sequentially formed on the substrate 20 through, for example, printing methods, such as screen printing, ink jet printing, gravure printing, flexography printing or the like, but not limited thereto.

The plurality of first conductive features 211 refers to the plurality of conductive features that is formed prior to the organic interlayer dielectric layer 23, while the plurality of second conductive features 212 refers to the plurality of conductive features that is formed subsequent to the organic interlayer dielectric layer 23. In some embodiments, as shown in FIG. 11, each of the plurality of first conductive features 211 and the plurality of second conductive features 212 includes a lower conductive layer (e.g., 211L, 212L) and an upper conductive layer (e.g., 211U, 212U) disposed on the lower conductive layer (e.g., 211L, 212L). However, in other embodiments, although not shown in FIG. 11, each of the plurality of first conductive features 211 and the plurality of second conductive features 212 includes a single conductive layer, for example, each first conductive feature 211 includes the upper conductive layer 211U and does not include the lower conductive layer 211L, and each second conductive feature 212 includes the upper conductive layer 212U and does not include the lower conductive layer 212L. Details (e.g., materials, cross-sectional widths) of the lower conductive layer (e.g., 211L, 212L), the upper conductive layer (e.g., 211U, 212U) and the organic interlayer dielectric layer 23 may refer to the above-described lower conductive layer (e.g., 11L, 12L), upper conductive layer (e.g., 11U, 12U) and first organic interlayer dielectric layer 13, and thus repetitions are omitted here.

In some embodiments, the plurality of first conductive features 211 includes one or more line portions 2110 and one or more pad portions 2112, and the plurality of second conductive features 212 includes one or more line portions 2120 and one or more pad portions 2122. Details of the line portions 2110, pad portions 2112, line portions 2120 and pad portions 2122 may refer to the above-described line portions 110, pad portions 112, line portions 120 and pad portions 122, and thus repetitions are omitted here.

In some embodiments, as shown in FIG. 11, the electronic device 2 further includes solder 25, and the electronic component 22 is bonded to the conductive feature 21 through the solder 25. By forming multiple conductive layers (e.g., 211L, 211U, 212L, 212U) at areas where the solder 15 is to be formed, namely, the pad portion (including a stack of one pad portion 2122 and a corresponding pad portion 2112) are a stack of a plurality of conductive layers (e.g., 211L, 211U, 212L, 212U), the risk of disconnection or poor connection between the electronic component 22 and the pad portion (e.g., 2112, 2122) due to pad portion leaching (conductive layer erosion/damage by the solder 15) during the soldering process can be reduced.

In some embodiments, as shown in FIG. 10, the electronic device 2 includes a plurality of electronic components 22. For example, the plurality of electronic components 22 includes a first electronic component 22A, a second electronic component 22B, a third electronic component 22C, a fourth electronic component 22D, a fifth electronic component 22E and a sixth electronic component 22F that are disposed on the flexible substrate (e.g., substrate 20) and electrically connected to the conductive features 21. The first electronic component 22A, the second electronic component 22B, the third electronic component 22C, the fourth electronic component 22D, the fifth electronic component 22E and the sixth electronic component 22F are, for example, a microcomputer, a display (e.g., an electronic paper display), a radio frequency chip, a sensor, a power circuit and a battery (or a power generation element such as a photovoltaic device or the like), respectively. In some embodiments, some of the plurality of electronic components 22 (e.g., the first electronic component 22A, the third electronic component 22C, the fourth electronic component 22D and the fifth electronic component 22E) may be electrically connected to the conductive features 21 through solders 15, while the rest (e.g., the second electronic component 22B and the sixth electronic component 22F) of the plurality of electronic components 22 may be electrically connected to the conductive features 21 through connection components 26. For example, the electronic device 2 includes a connection component 26A disposed on the flexible substrate (e.g., substrate 20) and electrically connected to the first electronic component 22A, and the second electronic component 22B is electrically connected to the connection component 26A. For example, the electronic device 2 includes a connection component 26B disposed on the flexible substrate (e.g., substrate 20) and electrically connected to the sixth electronic component 22F. The connection component 26A and/or the connection component 26B may include a connector.

In some embodiments, although not shown, the connection component 26A and/or the connection component 26B may include a bonding pad for bonding the second electronic component 22B and the sixth electronic component 22F. The second electronic component 22B and the sixth electronic component 22F may be an FPC or the like.

In some embodiments, the electronic device 2 further includes a protective layer 24, wherein the conductive feature 21 and the first electronic component 22A are covered by the protective layer 24, and the connection component 26A is exposed by the protective layer 24. FIG. 10 schematically indicates the coverage of the protective layer 24 with a dotted line. As shown in FIG. 10, the first electronic component 22A, the third electronic component 22C, the fourth electronic component 22D and the fifth electronic component 22E may be covered by the protective layer 24, while the connection components 26, the second electronic component 22B and the sixth electronic component 22F may be exposed by the protective layer 24.

In summary, in the embodiments of the disclosure, the multi-layer (e.g., two-layer) structure of at least one of the conductive features improves the flexibility of the at least one of conductive features, making the electronic device flexible or easy to bend. In addition, by forming multiple conductive layers at areas where the electronic component is to be bonded, the risk of disconnection or poor connection between the electronic component and the pad portions due to pad portion leaching during the soldering process can be reduced. Moreover, through the design that the first resin content of the lower conductive layer is greater than the second resin content of the upper conductive layer, the adhesion of the lower conductive layer to the substrate can be improved, thereby improving the problem of detachment/peeling of the conductive feature from the substrate. Furthermore, a protective layer may be formed to protect (e.g., to block water, oxygen and scratches) the conductive feature and/or the electronic component. In some embodiments, the conductive features may include the aforementioned peninsula structure to facilitate the bonding of the electronic component.

The above embodiments are only used to illustrate the technical solution of the disclosure, but not to limit it; although the disclosure has been described in detail with reference to the foregoing embodiments, those of ordinary skill in the art should understand that they can still modify the technical solutions recorded in the foregoing embodiments, or make equivalent substitutions for some or all of the technical features. However, these modifications or substitutions do not cause the essence of the corresponding technical solution to deviate from the scope of the technical solution of each embodiment of the disclosure.

Although the embodiments and advantages of the disclosure have been disclosed above, it should be understood that anyone with ordinary skill in the art can make changes, substitutions and modifications without departing from the spirit and scope of the disclosure. Furthermore, the features of various embodiments can be mixed and replaced at will to form other new embodiments. In addition, the protection scope of the disclosure is not limited to the processes, machines, manufacturing, material compositions, devices, methods and steps in the specific embodiments described in the specification. Any process, machine, manufacture, material compositions, device, method, and steps, now or hereafter developed, which may be understood from this disclosure by any person having ordinary knowledge in the art, may be used in accordance with this disclosure, provided that substantially the same function can be performed, or substantially the same result can be obtained, in the embodiments described herein. Accordingly, the scope of protection of the disclosure includes the processes, machines, manufacturing, material compositions, devices, methods, and steps described above. In addition, each claim constitutes an individual embodiment, and the scope of protection of the disclosure also includes a combination of the claims and embodiments. The scope of protection of the disclosure shall be as defined in the scope of the patent application attached hereto.

Anyone with ordinary knowledge in the relevant technical field can learn from the disclosure It is understood that processes, machines, manufacturing, material compositions, devices, methods and steps currently or developed in the future can be used according to the present disclosure as long as they can perform substantially the same functions or obtain substantially the same results in the embodiments described herein. Therefore, the protection scope of the present disclosure includes the above-mentioned processes, machines, manufacturing, material compositions, devices, methods and steps. In addition, each claim constitutes an individual embodiment, and the protection scope of the present disclosure also includes combinations of each claim and embodiment. The scope of protection of this disclosure shall be determined by the scope of the accompanying patent application.

What is claimed is:

1. An electronic device, comprising:
a flexible substrate;
a first conductive feature disposed on the flexible substrate;
a second conductive feature disposed on the first conductive feature;
a first organic interlayer dielectric layer disposed between the first conductive feature and the second conductive feature; and
an electronic component disposed on the flexible substrate and electrically connected to at least one of the first conductive feature and the second conductive feature,
wherein at least one of the first conductive feature and the second conductive feature comprises an organic material and a conductive material.

2. The electronic device according to claim 1, wherein at least one of the first conductive feature and the second conductive feature comprises a lower conductive layer and an upper conductive layer disposed on the lower conductive layer.

3. The electronic device according to claim 2, wherein in a cross-sectional view, a maximum width of the upper conductive layer is smaller than a maximum width of the lower conductive layer.

4. The electronic device according to claim 2, wherein the lower conductive layer has a first resin content, and the upper conductive layer has a second resin content less than the first resin content.

5. The electronic device according to claim 2, wherein the lower conductive layer has a first metal content, and the upper conductive layer has a second metal content greater than the first metal content.

6. The electronic device according to claim 1, further comprising:
a second organic interlayer dielectric layer disposed between the flexible substrate and the first conductive feature.

7. The electronic device according to claim 1, wherein the organic material comprises resin, and the conductive material comprises metal.

8. The electronic device according to claim 1, wherein the first conductive feature comprises a first pad portion, and the second conductive feature comprises a second pad portion disposed directly on the first pad portion, and the electronic component is bonded on the first pad portion and the second pad portion.

9. The electronic device according to claim 8, wherein the first organic interlayer dielectric layer comprises an opening, and the first pad portion and the second pad portion are disposed in the opening.

10. The electronic device according to claim 8, wherein a width of the first pad portion and a width of the second pad portion are equal to or greater than a width of the electronic component.

11. The electronic device according to claim 1, wherein the first organic interlayer dielectric layer comprises an opening, the second conductive feature comprises a pad portion disposed in the opening and a line portion disposed on the first organic interlayer dielectric layer and extending into the opening to be connected to the pad portion, and wherein:
the line portion comprises a necked end portion connected to the pad portion,
the necked end portion is located at an edge of the opening of the first organic interlayer dielectric layer and has a smaller line width than other portions of the line portion.

12. An electronic device, comprising:
a substrate;
a conductive feature disposed on the substrate and comprising a lower conductive layer and an upper conductive layer disposed on the lower conductive layer; and
an electronic component disposed on the substrate and electrically connected to the conductive feature,
wherein the lower conductive layer has a first resin content, and the upper conductive layer has a second resin content less than the first resin content.

13. An electronic device, comprising:
a flexible substrate;
a conductive feature disposed on the flexible substrate and comprising an organic material and a conductive material;
a first electronic component disposed on the flexible substrate and electrically connected to the conductive feature;
a connection component disposed on the flexible substrate and electrically connected to the first electronic component; and
a protective layer, wherein the conductive feature and the first electronic component are covered by the protective layer, and the connection component is exposed by the protective layer.

14. The electronic device according to claim 13, wherein the connection component comprises a connector or a bonding pad.

15. The electronic device according to claim 13, wherein the first electronic component comprises at least one of a sensor, a microprocessor, a radio frequency chip and a power supply IC.

16. The electronic device according to claim 13, further comprising:
a second electronic component electrically connected to the connection component.

17. The electronic device according to claim 16, wherein the second electronic component comprises an electronic paper display.

18. The electronic device according to claim 16, wherein the second electronic component comprises a battery or a power generation element.

19. The electronic device according to claim 16, wherein the second electronic component is exposed by the protective layer.

20. The electronic device according to claim 13, wherein the conductive feature comprises a pad portion, and the pad portion is a stack of a plurality of conductive layers.
